(19) United States
(12) Patent Application Publication
(10) Pub. No.: US 2006/0200711 A1
(43) Pub. Date: Sep. 7, 2006

(54) Network diagnostic systems and methods for processing network messages

(76) Inventors: Adam H. Schondelmayer, Cupertino, CA (US); Randy I. Oyadomari, San Jose, CA (US); Craig E. Foster, Santa Cruz, CA (US); A. Michael Lawson, Morgan Hill, CA (US); Scott D. Baxter, Mountain View, CA (US); Paul C. Abrahams, Fremont, CA (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(21) Appl. No.: 11/345,202

(22) Filed: Feb. 1, 2006

Related U.S. Application Data
(60) Provisional application No. 60/648,910, filed on Feb. 1, 2005.

(51) Int. Cl. G01R 31/28

(52) U.S. Cl. 714/712

(57) ABSTRACT

A networking system is provided. The networking system may include a diagnostic module. The diagnostic module may perform any of a variety of network diagnostic functions. The diagnostic module may include an analysis module, which may receive messages and perform any of a variety of network diagnostic functions using the messages it receives. The diagnostic module may include a logic module, which may receive network messages having a first format or structure, may process the network messages it receives into messages having a second format or structure, and may send the processed messages to the analysis module. The second format or structure may include any combination of a timestamp, a truncated portion of a network message, inter-packet meta-data, processing meta-data, and other suitable information.

### CROSS-REFERENCE TO RELATED APPLICATIONS

This application claims priority to and the benefit of U.S. provisional patent application Ser. No. 60/648,910, filed Feb. 1, 2005 and entitled NETWORK DIAGNOSTIC SYSTEMS AND METHODS FOR PROCESSING NETWORK MESSAGES, which is hereby incorporated by reference herein.

### BACKGROUND OF THE INVENTION

1. Field of the Invention

The present invention relates generally to networking systems. More particularly, embodiments of the invention relate generally to the testing of high speed data transmission systems and components.

2. Background Technology

Computer and data communications networks continue to proliferate due to declining costs, increasing performance of computer and networking equipment, and increasing demand for communication bandwidth. Communications networks—including wide area networks (“WANs”), local area networks (“LANs”), metropolitan area networks (“MANs”), and storage area networks (“SANS”)—allow increased productivity and use of distributed computers or stations through the sharing of resources, the transfer of voice and data, and the processing of voice, data and related information at the most efficient locations. Moreover, as organizations have recognized the economic benefits of using communications networks, network applications such as electronic mail, voice and data transfer, host access, and shared and distributed databases are increasingly used as a means to increase user productivity. This increased demand, together with the growing number of distributed computing resources, has resulted in a rapid expansion of the number of installed networks.

As the demand for networks has grown, network technology has developed to the point that many different physical configurations presently exist. Examples include Gigabit Ethernet (“GE”), 10 GE, Fiber Distributed Data Interface (“FDDI”), Fibre Channel (“FC”), Synchronous Optical Network (“SONET”) and InfiniBand networks. These networks, and others, typically conform to one of a variety of established standards, or protocols, which set forth rules that govern network access as well as communications between and among the network resources. Typically, such networks utilize different cabling systems, have different characteristic bandwidths and typically transmit data at different speeds. Network bandwidth, in particular, has been the driving consideration behind many advancements in the area of high speed communication systems, methods and devices.

For example, the ever-increasing demand for network bandwidth has resulted in the development of technology that increases the amount of data that can be pushed through a single channel on a network. Advancements in modulation techniques, coding algorithms and error correction have vastly increased the rates at which data can be transmitted across networks. For example, a few years ago, the highest rate that data could travel across a network was at about one Gigabit per second. This rate has increased to the point where data can travel across Ethernet and SONET networks at rates as high as 10 gigabits per second, or faster.

As communication networks have increased in size, speed and complexity however, they have become increasingly likely to develop a variety of problems that, in practice, have proven difficult to diagnose and resolve. Such problems are of particular concern in light of the continuing demand for high levels of network operational reliability and for increased network capacity.

The problems generally experienced in network communications can take a variety of forms and may occur as a result of a variety of different circumstances. Examples of circumstances, conditions and events that may give rise to network communication problems include the transmission of unnecessarily small frames of information, inefficient or incorrect routing of information, improper network configuration and superfluous network traffic, to name just a few. Such problems are aggravated by the fact that networks are continually changing and evolving due to growth, reconfiguration and introduction of new network topologies and protocols. Moreover, new network interconnection devices and software applications are constantly being introduced and implemented. Circumstances such as these highlight the need for effective, reliable, and flexible diagnostic mechanisms.

### SUMMARY

A need therefore exists for systems and methods that reduce the above-described disadvantages and problems and/or other disadvantages and problems.

In one embodiment, a networking system is provided. The network system may comprise a network, a network diagnostic or testing system, or other similar systems.

In one embodiment, the networking system may include at least one diagnostic module. The diagnostic module may perform any combination of a variety of network diagnostic functions. Examples of some network diagnostic functions may include a bit error rate tester network diagnostic function, a generator network diagnostic function, a jammer network diagnostic function, a protocol analyzer network diagnostic function, and a monitor network diagnostic function. The diagnostic module may perform network diagnostic functions using network messages received via any combination of a variety of serial protocols, physical layer protocols, and other network protocols. The diagnostic module may be configured to perform network diagnostic functions at or about the line speed of a network from which it receives network messages. However, the diagnostic module may be configured to perform network diagnostic functions at higher or lower speeds—depending on the particular configuration. The diagnostic module may be embodied in any of a variety of systems, such as, a printed circuit board, a blade, a chassis computing system, an appliance, and other similar systems.

In one embodiment, the diagnostic module may include an analysis module. The analysis module may receive messages and perform any of a variety of network diagnostic functions using the messages it receives.

In one embodiment, the diagnostic module may include a logic module. The logic module may receive network messages and perform any of a variety of network diagnostic functions using the network messages it receives. The logic module may receive network messages via any of a variety of network protocols.

In one embodiment, the logic module may receive network messages having any of a variety of formats or structures, may use the network messages it receives to generate messages having an alternate format or structure, and may send the generated messages to the analysis module. The analysis module may be configured to receive the messages having the alternate format or structure.

In one embodiment, the logic module may receive network messages via a network supporting up to a first bandwidth and may send the network messages to the analysis module in a second bandwidth supported by the analysis module.

In one embodiment, the logic module may receive network messages via a network supporting up to a first bandwidth, may use the network messages it receives to generate messages having an alternate format or structure, and may send the generated messages to the analysis module in a bandwidth supported by the analysis module. The analysis module may be configured to receive the messages having the alternate format or structure.

In one embodiment, a network message having an alternate format or structure may include any combination of a timestamp, a truncated portion of a network message, inter packet meta-data adapted to describe one or more network messages that occurred between network messages, processing meta-data adapted to describe how the alternate format or structure was generated, and other suitable information.

For purposes of summarizing, some aspects, advantages, and novel features have been described. Of course, it is to be understood that not necessarily all such aspects, advantages, or features will be embodied in any particular embodiment of the invention. Further, embodiments of the invention may comprise aspects, advantages, or features other than those that have been described. Some aspects, advantages, or features of embodiments of the invention may become more fully apparent from the following description and appended claims or may be learned by the practice of embodiments of the invention as set forth in this disclosure.

### BRIEF DESCRIPTION OF THE DRAWINGS

To further clarify the above and other advantages and features of embodiments of the present invention, a more particular description of invention will be rendered by reference to specific embodiments thereof which are illustrated in the appended drawings. It is appreciated that these drawings depict only typical embodiments of the invention and are therefore not to be considered limiting of its scope. Embodiments of the invention will be described and explained with additional specificity and detail through the use of the accompanying drawings in which:

FIG. 1 is a block diagram of a networking system, which may include a diagnostic module, according to an exemplary embodiment of the invention;

FIG. 2 is a block diagram illustrating an embodiment of the networking system shown in FIG. 1;

FIG. 3 is a block diagram of an exemplary embodiment of architecture that may be used to implement the diagnostic module shown in FIGS. 1 and 2;

FIG. 4A is a flow chart of a method, which may be used to perform one or more network diagnostic functions, in accordance with an embodiment of the invention;

FIG. 4B is a flow chart of a method, which may be used to perform one or more network diagnostic functions, in accordance with an embodiment of the invention;

FIG. 5A is a block diagram of an embodiment of the networking system shown in FIG. 1, according to an embodiment of the invention;

FIG. 5B is a block diagram of an embodiment of the networking system shown in FIG. 1, according to an embodiment of the invention;

FIG. 5C is a block diagram of an embodiment of the networking system shown FIG. 1, according to an embodiment of the invention;

FIG. 5D is a block diagram of an embodiment of the networking system shown in FIG. 1, according to an embodiment of the invention;

FIG. 6 is a block diagram of an embodiment of the networking system shown in FIG. 1; and

FIG. 7 is a flowchart illustrating a method which may be used to trigger a bit sequence capture, according to an embodiment of the invention.

### DETAILED DESCRIPTION OF THE PREFERRED EMBODIMENTS

Certain embodiments relate generally to networking systems, including the testing of high speed data transmission systems and components. Embodiments of the invention may be used in other contexts unrelated to testing systems and components and/or unrelated to high speed data transmission.

### Exemplary Networking System

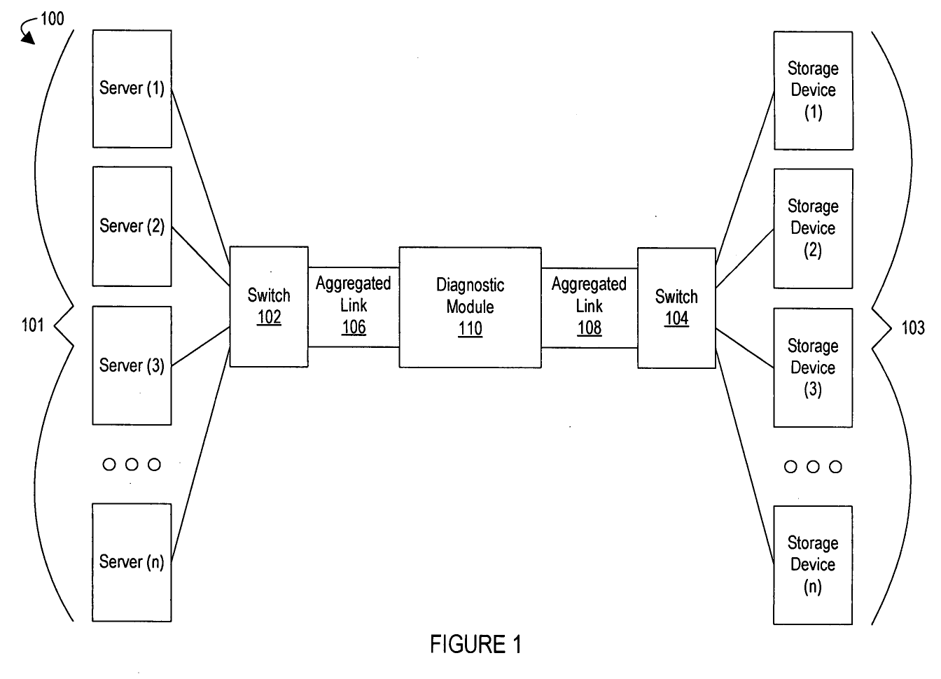

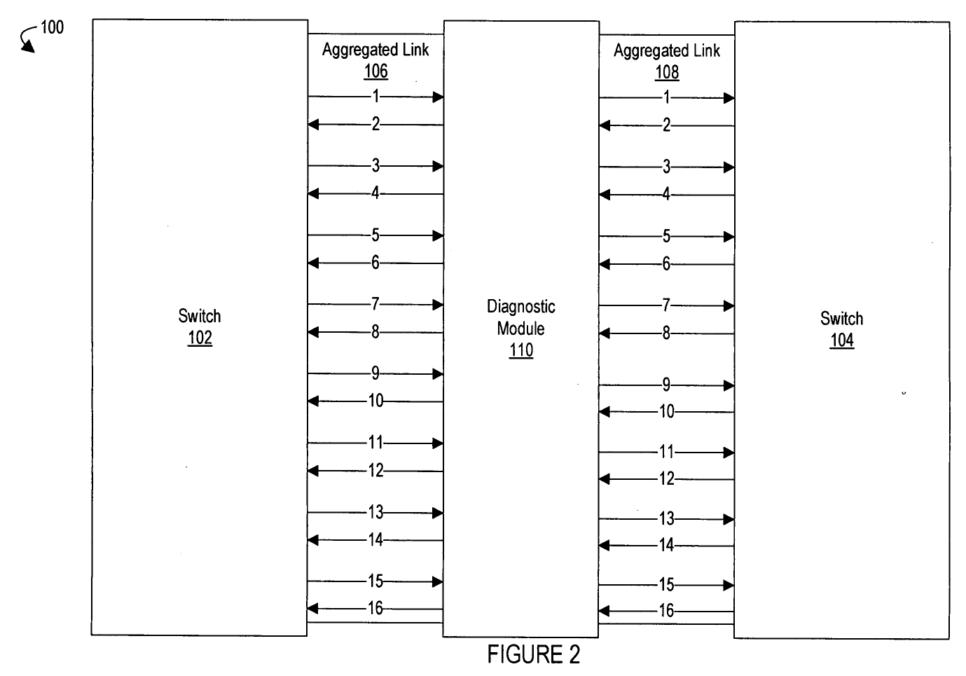

FIG. 1 is a block diagram of an exemplary networking system 100. FIG. 2 is a block diagram illustrating aggregated links included in the networking system 100 shown in FIG. 1. A diagnostic module 110 may be connected to and/or access the aggregated links 106, 108. The diagnostic module 110 can be disconnected if desired. The diagnostic module 110 can perform various operations on the data that is transmitted over the aggregated links 106, 108. As described in more detail below, the diagnostic module 110 can forward, passively tap, alter, monitor, and/or analyze data transmitted on the aggregated links 106, 108.

The networking system 100 may include one or more nodes. As used herein, a “node” includes, but is not limited to, a server or host; a client or storage device; a switch; a hub; a router; all or a portion of a SAN fabric; a diagnostic device; and any device that may be coupled to a network and that may receive and/or monitor a signal or data over at least a portion of a network, that may send and/or generate a signal or data over at least a portion of a network, or both.

In one embodiment, a signal (such as, an electrical signal, an optical signal, and the like) may be used to send and/or receive network messages over at least a portion of a network. As used herein, a “network message” includes, but is not limited to, a packet; a datagram; a frame; a data frame; a command frame; an ordered set; any unit of data capable of being routed (or otherwise transmitted) through a computer network; and the like. In one embodiment, a network message may comprise transmission characters used for data purposes, protocol management purposes, code violation errors, and the like. Also, an ordered set may include, a Start of Frame (“SOF”), an End of Frame (“EOF”), an Idle, a Receiver_Ready (“R_RDY”), a Loop Initialization Primitive (“LIP”), an Arbitrate (“ARB”), an Open (“OPN”), and Close (“CLS”)—such as, those used in certain embodiments of Fibre Channel. Of course, any ordered sets and/or any network messages of any other size, type, and/or configuration may be used, including, but not limited to, those from any other suitable protocols.

Nodes may communicate using suitable network protocols, including, but not limited to, serial protocols, physical layer protocols, channel protocols, packet-switching protocols, circuit-switching protocols, Ethernet, Fast Ethernet, Gigabit Ethernet, 10 Gigabit Ethernet, Fibre Channel, Fibre Channel Arbitrated Loop (“FC-AL”), Small Computer System Interface (“SCSI”), High Performance Parallel Interface (“HIPPI”), Serial Attached SCSI (“SAS”), Serial ATA (“SATA”), SAS/SATA, Serial SCSI Architecture (“SSA”), and the like.

### Aggregated Links

Nodes in a network may communicate using switches, aggregated links, other suitable means, or any combination thereof. For example, FIG. 1 illustrates servers 101 communicating with a switch 102, and storage devices 103 communicating with a switch 104. The switches 102 and 104 may communicate using one or more aggregated links (such as, aggregated links 106 and 108) and/or any other suitable line or connection.

As used herein, an “aggregated link” comprises a plurality of communication paths implemented as a single logical link. Because these communication paths are implemented as a single logical link, a switch or other type of node may use any of these communication paths to send a network message. Because the switch or node may use any of these communication paths, the switch or node need not wait for a particular communication path to become available in order to send a particular network message. Consequently, many communication bottlenecks may be avoided through load balancing communication among the various communications paths of an aggregated link.

In one embodiment, an aggregated link comprises a plurality of communication paths in one direction implemented as a single unidirectional logical link. In one embodiment, an aggregated link comprises a first plurality of communication paths in a first direction and a second plurality of communication paths in an opposing second direction implemented as a single bidirectional logical link.

The aggregated links 106 and 108 are preferably bidirectional to provide two or more communication paths in one direction and two or more communication paths in an opposite direction. For example, as shown in FIG. 2, the aggregated links 106 and 108 may comprise a first set of eight channels or other types of communication paths in a first direction from the switch 102 to the switch 104 (that is, channels 1, 3, 5, 7, 9, 11, 13, and 15) and a second set of eight channels or other types of communication paths in a second direction from the switch 104 to the switch 102 (that is, channels 2, 4, 6, 8, 10, 12, 14, and 16).

Because a bidirectional aggregated link may provide a plurality of communication paths in opposing directions, a first network message may be sent on any of the communication paths in one direction and a second network message sent in response to the first network message may be sent on any of the communication paths in the opposing direction. For example, as shown in FIG. 2, the switch 102 could send a first network message from a first node on any of the channels 1, 3, 5, 7, 9, 11, 13, and 15. The switch 104 could then forward the first message to a second node. The switch 104 could send a reply network message from the second node on any of the channels 2, 4, 6, 8, 10, 12, 14, and 16 to the switch 102. The switch 102 could then forward the reply network message to the first node.

A variety of configurations of structures may be used to implement an aggregated link's communication paths. An aggregated link's communications paths may be implemented using a single cable (such as, a fiber optic cable, copper wire, and other suitable communication mediums) or a plurality of cables. It will be appreciated that a cable may be bidirectional (which may provide at least one communication path in one direction and at least one communication path in an opposing direction) or unidirectional (which may provide at least one communication path in one direction). It will be appreciated, however, that cables are not required and that any other suitable means may be used to implement an aggregated link's communication paths.

In one embodiment, a trunk line may be used to implement some or all of an aggregated link's communication paths. The trunk line preferably comprises a plurality of cables, each cable providing at least one communication path. For example, in one embodiment, the trunk line may comprise 8 bidirectional cables providing 16 communication paths or channels.

In one embodiment, at least one cable providing a plurality of communication paths may be used to implement some or all of an aggregated link's communication paths. For example, an individual cable may provide a plurality of communication paths via multiplexing, such as wavelength division multiplexing, frequency division multiplexing, or time division multiplexing.

In one embodiment, some or all of the channels 1-16 of the aggregated links 106, 108 may each provide about 2 gigabits per second bandwidth. In one embodiment, an aggregated link may include 32 channels or communications paths (16 in one direction and 16 in an opposing direction) each providing about 1 gigabit per second bandwidth. These 32 channels or communication paths may be implemented, for example, using 16 bidirectional optical cables, or any number of other suitable cables or means. Of course, an aggregated link may provide less than 16, more than 16, less than 32, more than 32, or any other suitable number of channels or communication paths in any direction. Also, the channels or communication paths of an aggregated link may have any other suitable bandwidth, including lesser or greater bandwidths. Further, an aggregated link may provide the same number or a different number of communication paths in opposing directions.

Although FIGS. 1 and 2 illustrate a networking system 100 with aggregated links, it will be appreciated that the networking system 100, could use other suitable types of links, connections, or communications mediums in place of (or in addition to) aggregated links.

### Exemplary Diagnostic Module

With continued reference to FIGS. 1 and 2, the networking system 100 may comprise a network, network diagnostic system, a network testing system, or the like including diagnostic modules (such as, a diagnostic module 110), which may be configured to communicate network messages among nodes. In one embodiment, the diagnostic module 110 may comprise one or more hardware modules, one or more software modules, or both.

The diagnostic module 110 may be inserted between the switches 102 and 104 such that the network traffic along the aggregated links 106, 108 is available to the diagnostic module and/or is routed through the diagnostic module 110.

The diagnostic module 110 can both send and receive signals or data. Accordingly, using a signal, the diagnostic module 110 may receive one or more network messages from a node, send one or more network messages to a node, or both. For example, the switch 102 may send (via the aggregated link 106) a network message for the switch 104, which network message the diagnostic module 110 may receive and may send (via the aggregated link 108) to the switch 104. Similarly, the switch 104 may send (via the aggregated link 108) a network message for the switch 102, which network message the diagnostic module 10 may receive and may send (via the aggregated link 106) to the switch 102.

The diagnostic module 110 may perform a variety of network diagnostic functions. In performing some of these diagnostic functions, the diagnostic module 110 may be configured to be passive to network traffic comprising one or more network messages. If desired, the diagnostic module may receive at least some of the network traffic, and may transmit some or all of the received traffic. In performing other diagnostic functions, the diagnostic module 110 may be configured to alter some or all of the network traffic and/or generate network traffic.

It will be appreciated, however, that the traffic need not be routed through the diagnostic module 110. In addition, the switches 102 and 104 may communicate via a single aggregated link, which the diagnostic module 110 may passively tap, if desired.

The diagnostic module 110 may perform its network diagnostic functions on any type of network and/or network topology using any number of network protocols—including, but not limited to, those networks, topologies, and protocols recited in this application.

### Multi-Function Diagnostic Modules

As mentioned above, the diagnostic module 110 may perform variety of network diagnostic functions. The diagnostic module 110 may be configured to function as any combination of: a bit error rate tester, a protocol analyzer, a generator, a jammer, a monitor, and any other appropriate network diagnostic device.

Bit Error Rate Tester

In some embodiments, the diagnostic module 110 may function as a bit error rate tester. The bit error rate tester may generate and/or transmit an initial version of a bit sequence via a communication path. If desired, the initial version of the bit sequence may be user selected. The bit error rate tester may also receive a received version of the bit sequence via a communication path.

The bit error rate tester compares the received version of the bit sequence (or at least a portion of the received version) with the initial version of the bit sequence (or at least a portion of the initial version). In performing this comparison, the bit error rate test may determine whether the received version of the bit sequence (or at least a portion of the received version) matches and/or does not match the initial version of the bit sequence (or at least a portion of the initial version). The bit error tester may thus determine any differences between the compared bit sequences and may generate statistics at least partially derived from those differences. Examples of such statistics may include, but are not limited to, the total number of errors (such as, bits that did not match or lost bits), a bit error rate, and the like.

It will be appreciated that a particular protocol specification may require a bit error rate to be less than a specific value. Thus, a manufacturer of physical communication components and connections (such as, optical cables), communication chips, and the like may use the bit error rate tester to determine whether their components comply with a protocol-specified bit error rate. Also, when communication components are deployed, the bit error tester may be used to identify defects in a deployed physical communication path, which then may be physically inspected.

Protocol Analyzer

In some embodiments, the diagnostic module 110 may function as a protocol analyzer (or network analyzer), which may be used to capture data or a bit sequence for further analysis. The analysis of the captured data may, for example, diagnose data transmission faults, data transmission errors, performance errors (known generally as problem conditions), and/or other conditions.

As described below, the protocol analyzer may be configured to receive a bit sequence via one or more communication paths or channels. Typically, the bit sequence comprises one or more network messages, such as, packets, frames, or other protocol-adapted network messages. Preferably, the protocol analyzer may passively receive the network messages via passive network connections.

The protocol analyzer may be configured to compare the received the bit sequence (or at least a portion thereof) with one or more bit sequences or patterns. Before performing this comparison, the protocol analyzer may optionally apply one or more bit masks to the received bit sequence. In performing this comparison, the protocol analyzer may determine whether all or a portion of the received bit sequence (or the bit-masked version of the received bit sequence) matches and/or does not match the one or more bit patterns. In one embodiment, the bit patterns and/or the bit masks may be configured such that the bit patterns will (or will not) match with a received bit sequence that comprises a network message having particular characteristics—such as, for example, having an unusual network address, having a code violation or character error, having an unusual timestamp, having an incorrect CRC value, indicating a link re-initialization, and/or having a variety of other characteristics.

The protocol analyzer may detect a network message having any specified characteristics, which specified characteristics may be user-selected via user input. It will be appreciated that a specified characteristic could be the presence of an attribute or the lack of an attribute. Also, it will be appreciated that the network analyzer may detect a network message having particular characteristics using any other suitable method.

In response to detecting a network message having a set of one or more characteristics, the network analyzer may execute a capture of a bit sequence—which bit sequence may comprise network messages and/or portions of network messages. For example, in one embodiment, when the network analyzer receives a new network message, the network analyzer may buffer, cache, or otherwise store a series of network messages in a circular buffer. Once the circular buffer is filled, the network analyzer may overwrite (or otherwise replace) the oldest network message in the buffer with the newly received network message or messages. When the network analyzer receives a new network message, the network may detect whether the network message has a set of one or more specified characteristics. In response to detecting that the received network message has the one or more specified characteristics, the network analyzer may execute a capture (1) by ceasing to overwrite the buffer (thus capturing one or more network messages prior to detected message), (2) by overwriting at least a portion or percentage of the buffer with one or more newly received messages (thus capturing at least one network message prior to the detected message and at least network one message after the detected message), or (3) by overwriting the entire buffer (thus capturing one or more network messages after the detected message). In one embodiment, a user may specify via user input a percentage of the buffer to store messages before the detected message, a percentage of the buffer to store messages after the detected message, or both. In one embodiment, a protocol analyzer may convert a captured bit stream into another format.

In response to detecting a network message having a set of one or more characteristics, a network analyzer may generate a trigger adapted to initiate a capture of a bit sequence. Also, in response to receive a trigger adapted to initiate a capture of a bit sequence, a network analyzer may execute a capture of a bit sequence. For example, the network analyzer may be configured to send and/or receive a trigger signal among a plurality of network analyzers. In response to detecting that a received network message has the one or more specified characteristics, a network analyzer may execute a capture and/or send trigger signal to one or more network analyzers that are configured to execute a capture in response to receiving such a trigger signal. Further embodiments illustrating trigger signals and other capture systems are described in U.S. patent application Ser. No. 10/881,620 filed Jun. 30, 2004 and entitled PROPAGATION OF SIGNALS BETWEEN DEVICES FOR TRIGGERING CAPTURE OF NETWORK DATA, which is hereby incorporated by reference herein in its entirety.

It will be appreciated that a capture may be triggered in response to detecting any particular circumstance—whether matching a bit sequence and bit pattern, receiving an external trigger signal, detecting a state (such as, when a protocol analyzer's buffer is filled), detecting an event, detecting a multi-network-message event, detecting the absence of an event, detecting user input, or any other suitable circumstance.

The protocol analyzer may optionally be configured to filter network messages (for example, network messages having or lacking particular characteristics), such as, messages from a particular node, messages to a particular node, messages between or among a plurality of particular nodes, network messages of a particular format or type, messages having a particular type of error, and the like. Accordingly, using one or more bit masks, bit patterns, and the like, the protocol analyzer may be used identify network messages having particular characteristics and determine whether to store or to discard those network messages based at least in part upon those particular characteristics.

The protocol analyzer may optionally be configured to capture a portion of a network message. For example, the protocol analyzer may be configured to store at least a portion of a header portion of a network message, but discard at least a portion of a data payload. Thus, the protocol analyzer may be configured to capture and to discard any suitable portions of a network message.

It will be appreciated that a particular protocol specification may require network messages to have particular characteristics. Thus, a manufacturer of network nodes and the like may use the protocol analyzer to determine whether their goods comply with a protocol. Also, when nodes are deployed, the protocol analyzer may be used to identify defects in a deployed node or in other portions of a deployed network.

Generator

In some embodiments, the diagnostic module may function as a generator. The generator may generate and/or transmit a bit sequence via one or more communication paths or channels. Typically, the bit sequence comprises network messages, such as, packets, frames, or other protocol adapted network messages. The network messages may comprise simulated network traffic between nodes on a network. In one embodiment, the bit sequence may be a predefined sequence of messages. Advantageously, a network administrator may evaluate how the nodes (and/or other nodes on the network) respond to the simulated network traffic. Thus, the network administrator may be able to identify performance deviations and take appropriate measures to help avoid future performance deviations.

In one embodiment, the generator may execute a script to generate the simulated network traffic. The script may allow the generator to dynamically simulate network traffic by functioning as a state machine or in any other suitable manner. For example, a script might include one or more elements like the following: “In state X, if network message A is received, transmit network message B and move to state Y.” The generator may advantageously recognize network messages (and any characteristics thereof) in any other suitable manner, including but not limited to how a protocol analyzer may recognize network messages (and any characteristics thereof). The script may also include a time delay instructing the generator to wait an indicated amount of time after receiving a message before transmitting a message in response. In response to receiving a message, a generator may transmit a response message that is completely predefined. However, in response to receiving a message, a generator may transmit a response message that is not completely predefined, for example, a response message that includes some data or other portion of the received message.

Jammer

In some embodiments, the diagnostic module 110 may function as a jammer. The jammer may receive, generate, and/or transmit one or more bit sequences via one or more communication paths or channels. Typically, the bit sequences comprise network messages (such as, packets, frames, or other protocol-adapted network messages) comprising network traffic between nodes on a network. The jammer may be configured as an inline component of the network such that the jammer may receive and retransmit (or otherwise forward) network messages.

Prior to retransmitting the received network messages, the jammer may selectively alter at least a portion of the network traffic, which alterations may introduce protocol errors or other types of errors. Thus, by altering at least a portion of the network traffic, the jammer may generate traffic, which traffic may be used to test a network. For example, a network administrator may then evaluate how the nodes on the network respond to these errors. For example, a network system designer can perform any one of a number of different diagnostic tests to make determinations such as whether a system responded appropriately to incomplete, misplaced, or missing tasks or sequences; how misdirected or confusing frames are treated; and/or how misplaced ordered sets are treated. In some embodiments, the diagnostic module 110 may include any suitable jamming (or other network diagnostic system or method) disclosed in U.S. Pat. No. 6,268,808 B1 to Iryami et al., entitled HIGH SPEED DATA MODIFICATION SYSTEM AND METHOD, which is hereby incorporated by reference herein in its entirety.

In one embodiment, to determine which network messages to alter, the jammer may be configured to compare a received bit sequence—such as a network message—(or a portion of the received bit sequence) with one or more bit sequences or patterns. Before performing this comparison, the jammer may optionally apply one or more bit masks to the received bit sequence. In performing this comparison, the jammer may determine whether all or a portion of the received bit sequence (or the bit-masked version of the received bit sequence) matches and/or does not match the one or more bit patterns. In one embodiment, the bit patterns and/or the bit masks may be configured such that the bit patterns will (or will not) match with a received bit sequence (or portion thereof) when the received bit sequence comprises a network message from a particular node, a message to a particular node, a network message between or among a plurality of particular nodes, a network message of a particular format or type, and the like. Accordingly, the jammer may be configured to detect a network message having any specified characteristics. Upon detection of the network message having the specified characteristics, the jammer may alter the network message and/or one or more network messages following the network message.

Monitor

In some embodiments, the diagnostic module 110 may function as a monitor, which may be used to derive statistics from one or more network messages having particular characteristics, one or more conversations having particular characteristics, and the like.

As described below, the monitor may be configured to receive a bit sequence via one or more communication paths or channels. Typically, the monitor passively receives the network messages via one or more passive network connections.

To determine the network messages and/or the conversations from which statistics should be derived, the monitor may be configured to compare a received a bit sequence—such as a network message—(or a portion of the received bit sequence) with one or more bit sequences or patterns. Before performing this comparison, the monitor may optionally apply one or more bit masks to the received bit sequence. In performing this comparison, the monitor may determine whether all or a portion of the received bit sequence (or the bit-masked version of the received bit sequence) matches and/or does not match the one or more bit patterns. In one embodiment, the bit patterns and/or the bit masks may be configured such that the bit patterns will (or will not) match with a received bit sequence (or portion thereof) when the received bit sequence comprises a network message from a particular node, a network message to a particular node, a network message between or among a plurality of particular nodes, a network message of a particular format or type, a network message having a particular error, and the like. Accordingly, the monitor may be configured to detect a network message having any specified characteristics—including but not limited to whether the network message is associated with a particular conversation among nodes.

Upon detecting a network message having specified characteristics, the monitor may create and update table entries to maintain statistics for individual network messages and/or for conversations comprising packets between nodes. For example, a monitor may count the number of physical errors (such as, bit transmission errors, CRC error, and the like), protocol errors (such as, timeouts, missing network messages, retries, out of orders), other error conditions, protocol events (such as, an abort, a buffer-is-full message), and the like. Also, as an example, the monitor may create conversation-specific statistics, such as, the number of packets exchanged in a conversation, the response times associated with the packets exchanged in a conversation, transaction latency, block transfer size, transfer completion status, aggregate throughput, and the like. It will be appreciated that a specified characteristic could be the presence of an attribute or the lack of an attribute.

In some embodiments, the diagnostic module may include any features and/or perform any method described in U.S. patent application Ser. No. 10/769,202, entitled MULTI-PURPOSE NETWORK DIAGNOSTIC MODULES and filed on Jan. 30, 2004, which is hereby incorporated by reference herein in its entirety.

Exemplary Diagnostic Module Architecture

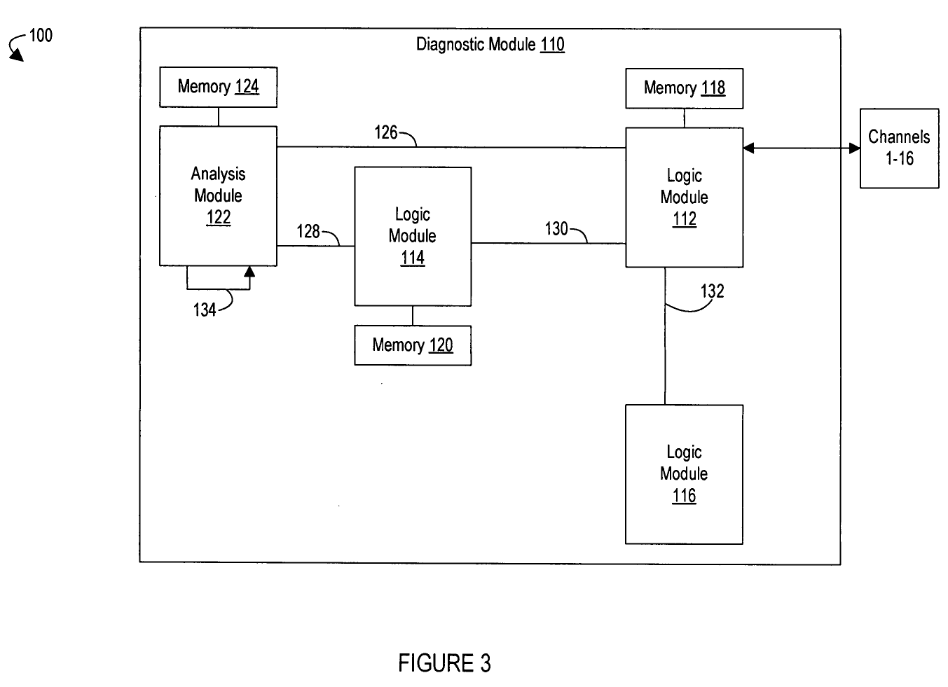

FIG. 3 is a block diagram of an exemplary embodiment of architecture that may be used to implement the diagnostic module 110 (FIGS. 1 and 2) using one or more hardware modules, software modules, or both.

As shown in FIG. 3, the diagnostic module 110 may include one or more logic modules (such as, logic modules 112, 114, and 116), which may comprise virtually any type of programmable circuit, such as, for example, a field programmable gate array (“FPGA”), a field programmable logic array (“FPLA”), a programmable logic array (“PLA”), or any programmable logic device. In one embodiment, the logic module 112, the logic module 114, the logic module 116, or any combination thereof may comprise a VIRTEX-II PRO™ FPGA, available from Xilinx, Inc., which has its corporate headquarters at 2100 Logic Drive, San Jose, Calif. 95124-3400 and has a website at www.xilinx.com. It will be appreciated, however, that the logic modules 112, 114, and 116 do not require the VIRTEX-II PRO™ FPGA or any other type of FPGA. In addition, any of the logic modules 112, 114, and 116 may comprise any combination of one or more software modules, one or more hardware modules, or both.

As shown in FIG. 3, some or all the logic modules 112, 114, and 116 may include, be connected to, be coupled to, or otherwise access storage devices including memory modules. For example, the logic module 112 may access the memory module 118, and the logic module 114 may access the memory module 120.

As shown in FIG. 3, the diagnostic module 110 may include an analysis module 122. In one embodiment, the analysis module 122 may comprise a network processor unit (“NPUs”), such as, the NP-ic network processor, available from EZchip Technologies Inc., which has its headquarters at 900 East Hamilton Avenue, Suite 100, Campbell, Calif. 95008, and has a website at www.ezchip.com. The NP-ic network processor comprises a single-chip network processor unit that may be programmable to perform various packet processing activities (such as, classification, modification, forwarding, policing, and the like) via a serial channel at about a 10-Gigabit per second speed. Of course, a network processor unit may be configured to perform packet processing activities at faster speeds or slower speeds, depending upon the intended purpose of the network processor unit.

It will be appreciated, however, that the analysis module 122 does not require the NP-ic network processor or any other type of network processor unit. In fact, the analysis module 122 may comprise one or more general purpose processors, application specific integrated circuits (ASICs), programmable circuits (such as, an FPGA, an FPLA, PLA, or any programmable logic device), a reduced instruction set computing (RISC) processor, a complex instruction set computing (CISC) processor, other hardware modules, software modules, or any combination thereof.

As shown in FIG. 3, the analysis module 122 may include, be connected to, be coupled to, or otherwise access one or more memory modules (such as, the memory module 124) of any suitable type. As shown in FIG. 3, the logic module 112 of the diagnostic module 110 may be configured to receive and/or send signals via one or more communication paths (such as, the channels 1-16 of the aggregated links 106 and 108 in FIG. 2, or any other type or number of communication paths). Accordingly, the logic module 112 may receive and/or send one or more network messages via those paths.

As shown in FIG. 3, the analysis module 122 and some or all of the logic modules 112, 114, and 116 may be interconnected in any suitable fashion using any suitable components. For example, the logic module 112 may be connected or coupled to the analysis module 122 using a connection 126, which may comprise any suitable connection through which the logic module 112 may communicate with the analysis module 122. In one embodiment, the logic module 112 may communicate with the analysis module 122 using the system packet interface (“SPI”)-4.2 standard or any other suitable standard. The analysis module 122 may be connected or coupled to the logic module 114 using a connection 128, which may comprise any suitable connection through which the analysis module 122 may communicate with the logic module 114. In one embodiment, the analysis module 122 may communicate with the logic module 114 using the SPI-4.2 standard or any other suitable standard. The logic module 114 may be connected or coupled to the logic module 112 using a connection 130, which may comprise any suitable connection through which the logic module 114 may communicate with the logic module 112. In one embodiment, the logic module 114 may communicate with the logic module 112 using the SPI-4.2 standard or any other suitable standard. The logic module 112 may be connected or coupled to the logic module 116 using a connection 132, which may comprise any suitable connection through which the logic module 112 may communicate with the logic module 116. In one embodiment, some or all of the connections 126, 128, 130, and 132 may comprise a bus (such as, a serial bus). Of course, the analysis module 122 and some or all of the logic modules 112, 114, and 116 may be interconnected in any other suitable fashion using any other suitable components.

In one embodiment, a connection 134 may be provided. The analysis module 122 may be configured to send an output signal via the connection 134 and receive that output signal via the connection 134, such that the analysis module 122 may perform additional processing on the messages it initially receives via the connection 126. For example, in performing some diagnostic functions, an analysis module may have limited diagnostic resources and may need to process certain messages through its system two or more times. Of course, an analysis module may need only to process messages through its system once—depending, for example, upon the diagnostic function being performed.

### Exemplary Network Diagnostic Methods

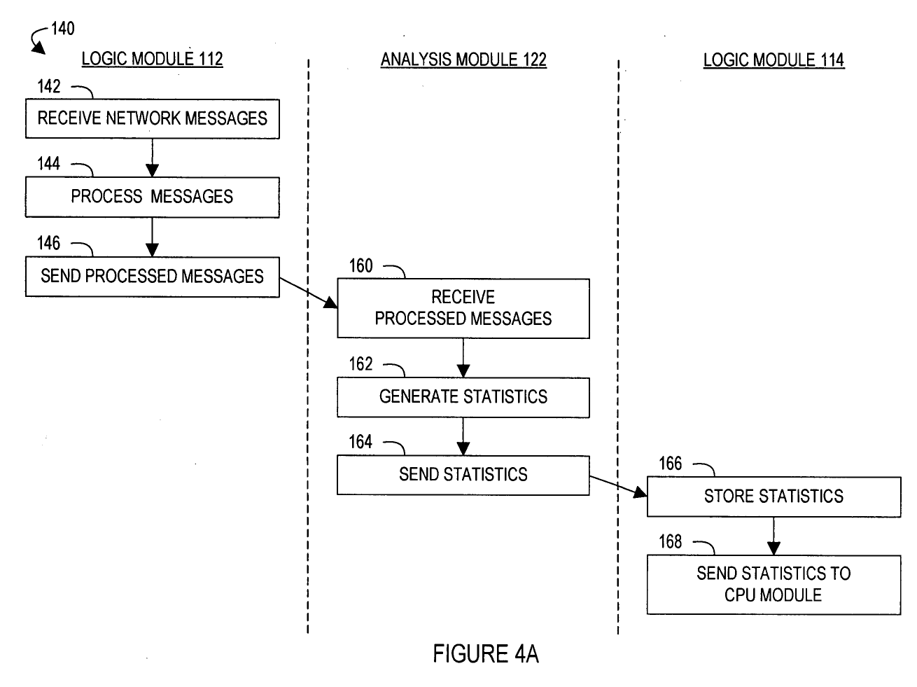

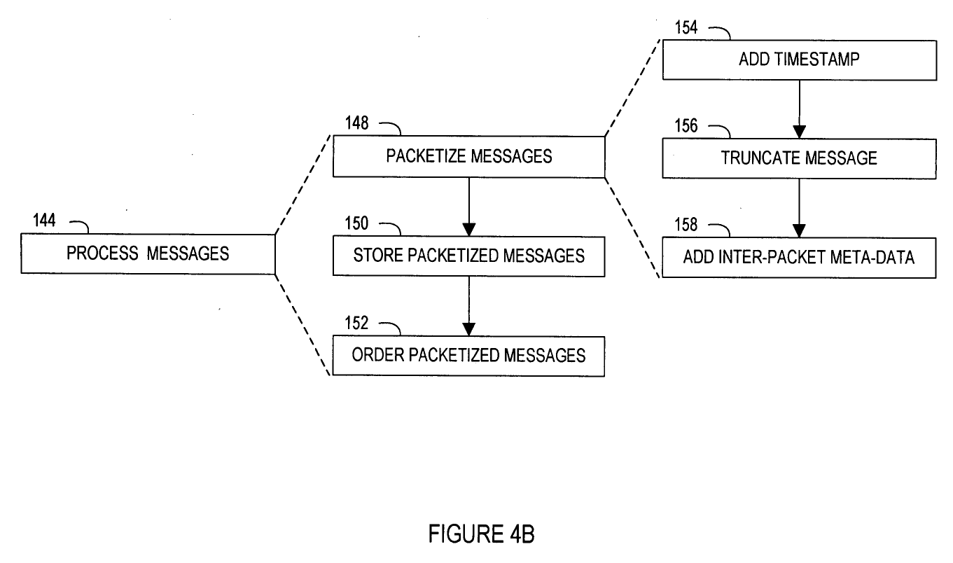

FIG. 4A is a flow chart of a method 140, which may be used to test a plurality of network messages sent among nodes, in accordance with an embodiment of the invention. The diagnostic module 110 may comprise a means for performing some or all of the method 140, but, of course, any other suitable system may perform some or all of the method 140.

Referring to FIGS. 3 and 4A, at the block 142, the logic module 112 may receive network messages from one or more communication paths. As described above, such communication paths may form at least a part of an aggregated link. In addition, such communication paths may form at least a part of unidirectional link or at least a part of a bidirectional link. Further, such communications paths may be implemented using a single cable, a plurality of cables and/or any other suitable medium. In one embodiment, the logic module 112 may receive network messages from an aggregated link. In one embodiment, the logic module 112 may receive network messages from a trunk line.

At the block 144, the logic module 112 may optionally process the received network messages into one or more messages having an alternative, substitute, different, or otherwise alternate format or structure adapted to be received by the analysis module 122 and adapted to be used by the analysis module 122 to perform one or more network diagnostic functions.

At a block 146, the logic module 112 may forward the processed messages (or the unprocessed messages) to the analysis module 122 via the connection 126.

Processing Received Network Messages

FIG. 4B is a block diagram illustrating an exemplary embodiment of how the logic module 112 may process received network messages at the block 144 (FIG. 4A). It will be appreciated that the received network messages may have a first format adapted to comply with at least one network protocol supported by the networking system 100. In processing the network messages at the block 144, the logic module 112 may optionally process a set of one or more received messages into a set of one or more packets, frames, or otherwise encapsulated messages having a second, alternate format. Thus, at the block 144, the logic module 112 may packetize or otherwise encapsulate at least a portion of the received network messages into messages adapted to be processed by the analysis module 122.

At a block 150, the logic module may 112 may buffer or otherwise store the packetized or encapsulated messages in the memory module 118 and, at the block 152, may retrieve and then order the packetized or encapsulated messages. In some instances, the logic module 112 may order some or all of the packetized messages prior to storing them, after storing them, or a combination of both. In some instances, the logic module 112 may store some or all of the received network messages in the memory module 118 prior to packetizing them, after packetizing them, or a combination of both. In fact, the logic module 112 may perform some or all of the blocks 148, 150, 152 in any suitable order, if desired.

As shown in FIG. 4B, to packetize a received network message, the logic module 112 may, at a block 154, generate and add a timestamp to the network message. The timestamp may indicate when the logic module 112 received at least a portion of the network message or any other suitable time.

At a block 156 in FIG. 4B, the logic module 112 may truncate at least a portion of the received network message. For example, in some embodiments, the network message may include a header portion, a payload or other data portion, and/or other portions. The logic module 112 may discard or otherwise remove some or at least a portion of the data portion—thus truncating the network message. In some embodiments, the logic module 112 may be configured to detect the type of network message and dynamically determine which, if any, portions of a network message may be removed. For example, the logic module 112 may be configured to detect that a network message includes a nested or layered message within the network message's data portion—thus allowing the logic module to retain any desired portions of the nested message and remove any other portions.

At a block 156 in FIG. 4B, the logic module 112 may optionally add (to the received network message) meta-data adapted to describe at least a portion of the network messages that occurred between the received network message and another network message. For example, a received network message may comprise a packet, a frame, or the like that is received after an earlier network message that comprised a packet, a frame, or the like. The meta-data may comprise data describing the number and/or types of ordered sets that were received between the earlier network message and the received network message.

As shown above, the logic module 112 may, at the block 144, process the received network messages into one or more packetized messages having an alternate format adapted to be processed by the analysis module 122. The packetized messages may include any suitable combination of: a timestamp, at least a portion of a network message (which may or may not be at least partially truncated), inter-packet meta-data, and/or any other suitable data that may be useful for the analysis module 122. In one embodiment, a packetized message may also include one or more delimiters adapted to indicate the start and end of the packetized message and/or processing meta-data adapted to describe how the received network message was truncated or otherwise processed by the logic module 112. Accordingly, the analysis module 122 may advantageously use the timestamp, any portion of a received network message, the inter-packet meta-data, the delimiter, the processing-meta data, and/or any other data provided by the packetized messages to determine how to perform various diagnostic functions.

Processing received network messages may provide advantages. For example, in one embodiment, the analysis module 122 may comprise a network processor unit (such as, the NP-1c network processor), and the aggregated links 106 and 108 may provide 16 channels having about a 2-gigabit per second bandwidth (thus, a total of about 32 gigabits per second). As mentioned above, the NP-1c may perform various packet processing activities (such as, classification, modification, forwarding, policing, and the like) via a serial channel having about a 10-gigabit per second bandwidth. By truncating certain network messages and/or by replacing at least a portion of the network messages with inter-packet meta-data, the logic module 112 may process the 16 channels of about 2 gigabits each into a serialized stream of packets of about a 10-Gigabit bandwidth. An NP-1c could be then configured to perform various network diagnostic functions (such as, monitoring and/or any other network diagnostic function) upon the serialized stream of packets of about a 10-Gigabit per second bandwidth, which may actually represent about a total of about 32 gigabits per second of network messages. Thus, in one embodiment, the diagnostic module 110 may perform, at line speed, monitoring (and/or other network diagnostic functions) of network messages having bandwidth of up to about 32 gigabits per second. Also, to perform monitoring (and/or other network diagnostic functions) of network messages having a first bandwidth at line speed, the diagnostic module 110 may process the network messages into a serialized stream of packetized messages having up to seventy percent less bandwidth than the first bandwidth. Also, the diagnostic module 110 may perform, at line speed, monitoring (and/or other network diagnostic functions) of an aggregated link, such as, an aggregated link of 16 communication paths or channels with each path or channel having about a 2-gigabit per second bandwidth. Of course, the diagnostic module 110 may monitor (and/or perform other network diagnostic functions) networks and communication paths having more bandwidth or less bandwidth. Also, logic module 112 may send the packetized messages at any other suitable bandwidth relative to the source bandwidth. Further, because the block 144 (FIGS. 4A and 4B) is optional, logic module 112 need not process incoming network messages in any fashion before forwarding them to the analysis module 122.

As another example, processing received network messages may optionally provide a diagnostic module that may be configured to perform network diagnostic functions on a plurality of data protocols. For example, the logic module 112 may be loaded with a first set of instructions adapted to process network messages from a first protocol and subsequently loaded with a second set of instructions adapted to network messages from a second protocol. Preferably, both the first and second set of instructions may be configured to send similar or the same packetized messages to the analysis module 122—thus permitting the analysis module 122 to support multiple protocols.

Statistics Management

As shown in FIG. 4A, the analysis module 122 may receive the processed messages at the block 160. At the block 162, the network module 122 may function as a monitor to generate one or more statistics. For example, the analysis module 122 may use one or more tables or other data structures stored in the attached memory module 124 and/or in an on-board memory module (not shown) to count the number of physical errors (such as, bit transmission errors; CRC error, and the like), protocol errors (such as, timeouts, missing network messages, retries, out of orders), protocol events (such as, an abort, a buffer-is-full message), and the like. Also, as an example, the analysis module 122 may create conversation-specific statistics, such as, the number of packets exchanged in a conversation, the response times associated with the packets exchanged in a conversation, and the like. Of course, the analysis module 122 may generate any of a variety of other suitable statistics.

As shown in FIG. 4A, the analysis module 122 may, at the block 164, send all or a portion of the statistics to the logic module 114 via the connection 128. The logic module 114 may receive the statistics and, at the block 166, may optionally buffer or otherwise store the statistics in the memory module 120.

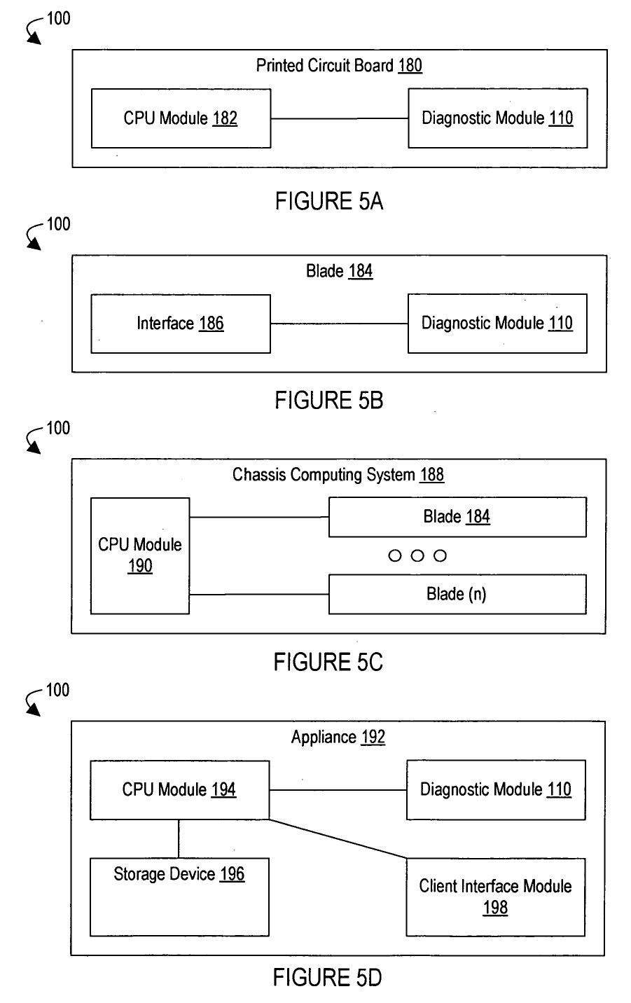

At the block 168, the logic module 114 may communicate with a central processing unit (“CPU”) module, such as, a central processing unit or other suitable processor, which may prepare the statistics for client retrieval, as shown, for example, in FIGS. 5A-5D.

### Exemplary Networking Systems

It will be appreciated that the diagnostic module 110 may be used to implement a variety of networking systems, networking diagnostic systems, and the like. FIGS. 5A-5D illustrate various embodiments of the networking system 100 shown in FIG. 1.

As shown in FIG. 5A, the networking system 100 may include a printed circuit board 180, which may include a CPU module 182 and the diagnostic module 110. The diagnostic module 110 may be coupled to the CPU module 182 using a PCI interface. or any other suitable interface. Thus, in one embodiment, the logic module 114 (FIG. 3) may, at the block 168 (FIG. 4A), send the statistics or any other suitable network diagnostic data to the CPU Module 182 via a suitable interface. The printed circuit board 180 may include one or more CPU modules and may include one or more diagnostic modules, depending upon the particular configuration.

As shown in FIG. 5B, the networking system 100 may include a blade 184, which may comprise a printed circuit board. The blade 184 may include an interface 186 and the diagnostic module 110. The diagnostic module 110 may be coupled to the interface 186.

As shown in FIG. 5C, a chassis computing system 188 may include one or more CPU modules (such as, a CPU module 190), which may be adapted to interface with one, two, or more blades or other printed circuit boards. For example, a blade may have an interface (such as, the interface 186) though which the diagnostic module 110 may send network diagnostic data to the CPU module. The chassis computer system adapted to receive one or more printed circuit boards or blades.

A CPU module, such as, the CPU modules 182 and 190, may transmit the network diagnostic data it receives to a local storage device, a remote storage device, or any other suitable system for retrieval and/or further analysis of the diagnostic data. A client software program may retrieve, access, and/or manipulate the diagnostic data for any suitable purpose. Examples of systems and methods for storing and retrieving network diagnostic data include, but are not limited to, those described in U.S. patent application Ser. No. 10/307,272, entitled A SYSTEM AND METHOD FOR NETWORK TRAFFIC AND I/O TRANSACTION MONITORING OF A HIGH SPEED COMMUNICATIONS NETWORK and filed Nov. 27, 2002, which is hereby incorporated by reference herein in its entirety.

As shown in FIG. 5D, an appliance (such as, an appliance 192) may comprise one or more diagnostic modules (such as, the diagnostic module 110). Depending on the particular configuration, the appliance 192 may include any suitable combination of one or more CPU modules (such as, a CPU module 194) and one or more diagnostic modules. In one embodiment, an appliance may include and/or be in communication with one or more storage devices (such as, a storage device 196), which may advantageously be used for storing any suitable diagnostic data, statistics, and the like. In one embodiment, an appliance may include and/or be in communication with one or more client interface modules (such as, a client interface module 198), which may advantageously be used for displaying information to a user, receiving user input from a client software program, sending information to a client software program, or both. The appliance may also include and/or be in communication with one or more display devices (such as, a monitor) adapted to display information, one or more user input devices (such as, a keyboard, a mouse, a touch screen, and the like) adapted to receive user input, or both.

### Statistical Triggering of Bit Sequence Captures

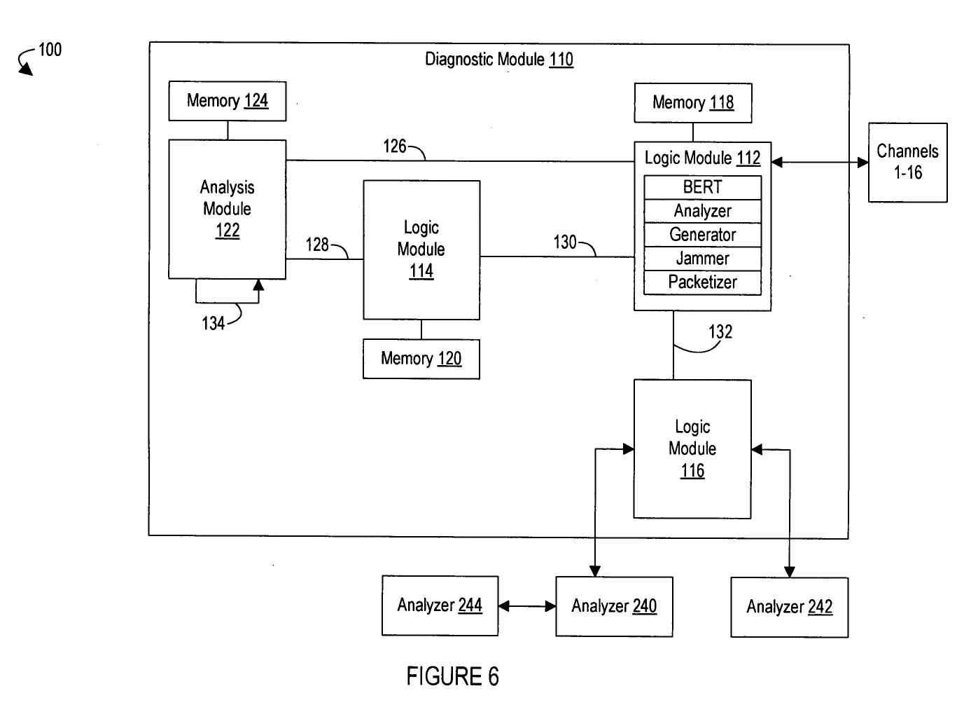

As mentioned above, the diagnostic module 110 may provide any combination of network diagnostic functions. For example, FIG. 6 is a block diagram illustrating an embodiment of the diagnostic module 110 in which the diagnostic module 110 may be configured to perform a variety of diagnostic functions. For example, the logic module 112 may be configured to receive loaded logic or instructions to perform as a bit error rate tester, an analyzer, a generator, a jammer, as well as performing the packetizing and/or other functionality shown in FIG. 4B. As shown in FIGS. 4A and 4B, the analysis module 122 may be configured to perform as a monitor; however, the analysis module 122 may be configured to perform as a bit error rate tester, an analyzer, a generator, a jammer, and the like.

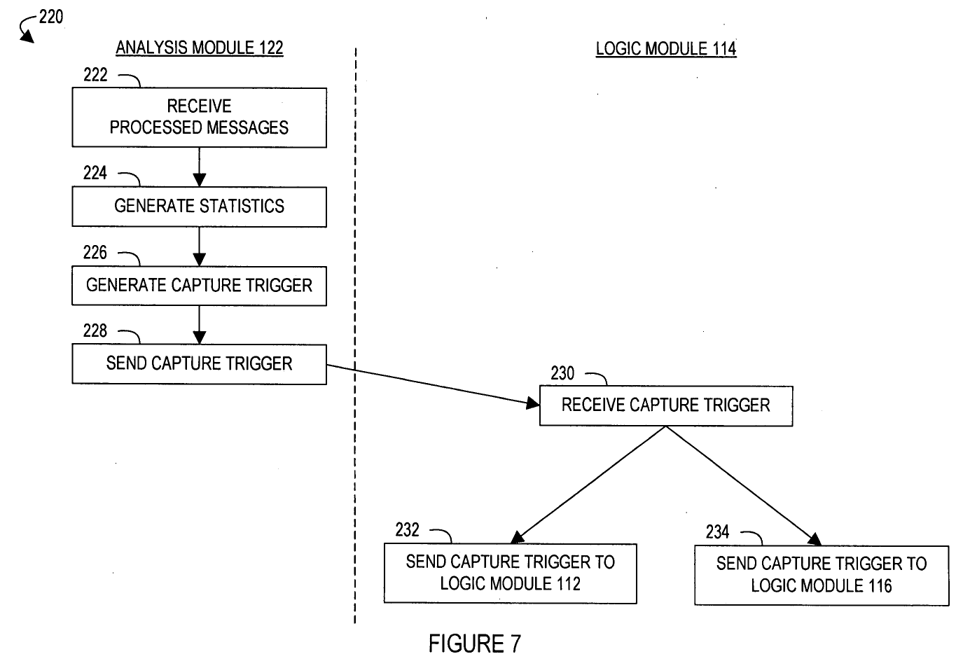

In one embodiment, the diagnostic module 1 10 may be configured to trigger a bit sequence capture, such as, those described above with reference to an analyzer. For example, FIG. 7 is a flowchart illustrating a method 220 which may be used to trigger a bit sequence capture by an analyzer or other network diagnostic device. As shown in FIG. 7, the analysis module 122 may receive one or more messages at a block 222, which may be optionally processed by the logic module 112 as shown in FIG. 4B. At the block 224, the analysis module 122 may generate statistics. At the block 226, the analysis module may detect at least one specified statistic, which specified statistic may be a user-specified statistic, statistical range, or the like.

In response to detecting the at least one specified statistic, the analysis module 122 may, at the block 226, generate a trigger adapted to initiate a capture of a bit sequence, such as, a capture of a bit sequence by an analyzer.

Referring to FIGS. 6 and 7, at a block 228, the analysis module 122 may send the capture trigger signal to the logic module 114, which receives the capture. trigger signal at the block 230.

The logic module 114 may propagate the capture trigger signal to one or more analyzers configured to execute a capture of a bit sequence in response to receiving the trigger signal.

As shown in FIG. 7, at the block 232, the logic module 114 may send a capture trigger to the logic module 112, which may then execute any suitable bit capture on any buffered bit sequences. For example, the logic module 112 may perform as a packetizer and as an analyzer. Accordingly, the logic module 112 may access a plurality of buffers, such as, a first buffer for the packetized messages to be sent to the analysis module 122 and a second buffer for the received network messages for executing a bit sequence capture. Accordingly, the logic module 112 may execute a bit sequence capture on the second buffer.

In one embodiment, the logic module 112 may packetize messages after removing the received network messages from a buffer, and the bit sequence capture may be executed on the network messages on that buffer.

In one embodiment, the logic module 112 may packetize messages before storing the messages in buffer, and the bit sequence capture may be executed on the packetized messages in the buffer. In some instances, it may be desirable to have the captured packetized messages depacketized (or processed in some other way) to accommodate a particular network diagnostic component.

As mentioned above, for a typical analyzer, the capture bit sequences generally comprise one or more network messages (or portions thereof). Further embodiments other capture systems are described in U.S. patent application Ser. No. 10/218,343 filed Aug. 13, 2002 and entitled SYSTEM AND METHOD FOR TRIGGERING COMMUNICATIONS DATA CAPTURE, which is hereby incorporated by reference herein in its entirety.

As shown in FIG. 7, at the block 234, the logic module 114 may send a capture trigger signal to the logic module 116. The logic module 116 may then forward the capture trigger signal to one or more analyzers (such as, analyzers 240 and 242 in FIG. 6), which, in response, may execute a bit capture and may also forward the capture trigger signal to yet another analyzer (such as, an analyzer 244 in FIG. 6). Thus, as shown in FIG. 6, the logic module 116 may be used to create a chain of devices configured to propagate capture trigger signals between and among a plurality of analyzers.

In some instances, a logic module (such as, the logic module 116) might break such a chain if it were reloaded. For example, a logic module that may provide a variety of diagnostic functions and may need to be reloaded to provide some of those functions. Accordingly, rather than including the chain-linking functionality in the logic module 112 (which may perform a variety of functions depending on the particular configuration), the chain-linking functionality may be providing via the logic module 116—which permits the logic module 112 to reloaded with various configurations without breaking the chain. As mentioned above, further embodiments illustrating trigger signals and other capture systems are described in U.S. patent application Ser. No. 10/881,620 filed Jun. 30, 2004 and entitled PROPAGATION OF SIGNALS BETWEEN DEVICES FOR TRIGGERING CAPTURE OF NETWORK DATA, which is incorporated by reference herein.

### Exemplary Ethernet LAN Statistics

As described above, a monitor may generate a variety of statistics, which, in some embodiments, may be used to trigger a bit sequence capture. In some embodiments, statistics may be generated for Ethernet LANs or other networks.

In one embodiment, the Ethernet LAN statistics may include protocol distribution statistics, which may include any combination of the following: the number of packets for a protocol, the percent of all packets which were this protocol, the number of octects (bytes) for this protocol, the percent of all bytes which were this protocol, the percent of the theoretical bandwidth used by this protocol, and/or other like statistics.

In one embodiment, the Ethernet LAN statistics may include a variety of host-specific stats, which may include any combination of the following: the number of frames destined for the host, the number of frames from the host, the number of frames to and from the host, the number of bytes destined for the host, the number of bytes from the host, the number of bytes to and from the host, the number of errors from the host, the number of broadcast frames from the host, the number of multicast frames from the host, the percent of all frames that are destined for the host, the percent of all frames that are from the host, the percent of all frames that are to or from the host, the percent of all bytes that are destined for the host, the percent of all bytes that are from the host, the percent of all bytes that are to or from the host, the percent of the theoretical bandwidth used by traffic destined for the host, the percent of the theoretical bandwidth used by traffic from the host, the percent of the theoretical bandwidth used by traffic to and from the host, the average size in bytes for frames that are destined for the host, the average size in bytes for frames that are from the host, the average size in bytes for all frames to or from the host, and/or other like statistics.

In one embodiment, the Ethernet LAN statistics may include a variety of host-specific, network-layer statistics, such as, for a particular virtual LAN. The host-specific, network-layer statistics may include any combination of: the number of frames in the number of frames out, the number of frames in and out, the number of bytes in, the number of bytes out, the number of bytes in and out, the number of non-unicast frames, the percent of all frames that are destined for the host, the percent of all frames that are from the host, the percent of all frames that are to or from the host, the percent of all bytes that are destined for the host, the percent of all bytes that are from the host, the percent of all bytes that are to or from the host, the percent of the theoretical bandwidth used by traffic destined for the host, the percent of the theoretical bandwidth used by traffic from the host, the percent of the theoretical bandwidth used by traffic to and from the host, the average size in bytes for frames that are destined for the host, the average size in bytes for frames that are from the host, the average size in bytes for all frames to or from the host, and/or other like statistics.

In one embodiment, the Ethernet LAN statistics may include a variety of host-specific, application-layer statistics, such as, for a particular virtual LAN identifier and application protocol. The host-specific, application-layer statistics may include any combination of: the number of frames in the number of frames out, the number of frames in and out, the number of bytes in, the number of bytes out, the number of bytes in and out, the percent of all frames that are destined for the host, the percent of all frames that are from the host, the percent of all frames that are to or from the host, the percent of all bytes that are destined for the host, the percent of all bytes that are from the host, the percent of all bytes that are to or from the host, the percent of the theoretical bandwidth used by traffic destined for the host, the percent of the theoretical bandwidth used by traffic from the host, the percent of the theoretical bandwidth used by traffic to and from the host, the average size in bytes for frames that are destined for the host, the average size in bytes for frames that are from the host, the average size in bytes for all frames to or from the host, and/or other like statistics.

In one embodiment, the Ethernet LAN statistics may include a variety of multi-host statistics, such as, for a pair of hosts. The multi-host statistics may include any combination of the following: the number of frames from a first host to a second host, the number of frames from the second host to the first host, the number of frames between the first host and the second host, the number of bytes from the first host to the second host, the number of bytes from the second host to the first host, the number of bytes between the first host and the second host, the percent of all frames that are from the first host to the second host, the percent of all frames that are from the second host to the first host, the percent of all frames that are the conversation between the first host and the second host, the percent of all bytes that are from the first host to the second host, the percent of all bytes that are from the second host to the first host, the percent of all bytes that are the conversation between the first host and the second host, the percent of the theoretical bandwidth used by data from the first host to the second host, the percent of the theoretical bandwidth used by data from the second host to the first host, the percent of the theoretical bandwidth used by the conversation between the first host and the second host, the average size in bytes for frames from the first host to the second host, the average size in bytes for frames from the second host to the first host, the average size in bytes for all frames between the first host and the second host, the number of errors from the first host to the second host, the number of errors from the second host to the first host, the number of errors between the first host and the second host, and/or other like statistics.

In one embodiment, the Ethernet LAN statistics may include a variety of multi-host, network-layer statistics, such as, for a particular virtual LAN. The multi-host, network-layer statistics may include any combination of the following: the number of frames from a first host to a second host, the number of frames from the second host to the first host, the number of frames between the first host and the second host, the number of bytes from the first host to the second host, the number of bytes from the second host to the first host, the number of bytes between the first host and the second host, the percent of all frames that are from the first host to the second host, the percent of all frames that are from the second host to the first host, the percent of all frames that are the conversation between the first host and the second host, the percent of all bytes that are from the first host to the second host, the percent of all bytes that are from the second host to the first host, the percent of all bytes that are the conversation between the first host and the second host, the percent of the theoretical bandwidth used by data from the first host to the second host, the percent of the theoretical bandwidth used by data from the second host to the first host, the percent of the theoretical bandwidth used by the conversation between the first host and the second host, the average size in bytes for frames from the first host to the second host, the average size in bytes for frames from the second host to the first host, the average size in bytes for all frames between the first host and the second host, and/or other like statistics.

In one embodiment, the Ethernet LAN statistics may include a variety of multi-host, application-layer statistics, such as, for a particular virtual LAN identifier and application protocol. The multi-host, application-layer statistics may include any combination of the following: the number of frames from a first host to a second host, the number of frames from the second host to the first host, the number of frames between the first host and the second host, the number of bytes from the first host to the second host, the number of bytes from the second host to the first host, the number of bytes between the first host and the second host, the percent of all frames that are from the first host to the second host, the percent of all frames that are from the second host to the first host, the percent of all frames that are the conversation between the first host and the second host, the percent of all bytes that are from the first host to the second host, the percent of all bytes that are from the second host to the first host, the percent of all bytes that are the conversation between the first host and the second host, the percent of the theoretical bandwidth used by data from the first host to the second host, the percent of the theoretical bandwidth used by data from the second host to the first host, the percent of the theoretical bandwidth used by the conversation between the first host and the second host, the average size in bytes for frames from the first host to the second host, the average size in bytes for frames from the second host to the first host, the average size in bytes for all frames between the first host and the second host, and/or other like statistics.

In one embodiment, the Ethernet LAN statistics may include a variety of utilization-related statistics, which may include any combination of the following: the number of frames captured, the number of frames received, the number of broadcast frames, the number of multicast frames, the number of unicast frames, the number of bytes received, the percentage of the max theoretical throughput used, and/or other like statistics.

In one embodiment, the Ethernet LAN statistics may include a variety of error-related statistics, which may include any combination of the following: the number of frame errors, the number of CRC alignment errors, the number of undersized frames, the number of oversized frames, the number of frame fragments, the number of jabber frames, the number of collisions, the number of packets dropped, and/or other like statistics.

In one embodiment, the Ethernet LAN statistics may include a variety of frame-size statistics, which may include any combination of the following: the total number of frames, the total number of bytes, the number of undersize frames, the percent of all frames that are undersized, the number of frames 64 bytes long, the percent of all frames that are 64 bytes long, the number of frames 65-127 bytes long, the percent of all frames that are 65-127 bytes long, the number of frames 128-255 bytes long, the percent of all frames which are 128-255 bytes long, the number of frames 256-511 bytes long, the percent of all frames that are 256-511 bytes long, the number of frames 512-1023 bytes long, the percent of all frames that are 512-1023 bytes long, the number of frames 1024-1518 bytes long, the percent of all frames that are 1024-1518 bytes long, the number of oversize frames, the percent of all frames that are oversized, the average size in bytes for all frames, and/or other like statistics.

In one embodiment, the statistics may include a variety of other host-specific, application-layer statistics, such as, for a particular application protocol. These host-specific, application-layer statistics may include a minimum response time for a host, a maximum response time for a host, an average response time for a host, a total response time for a host, a number of connections to the host for a particular application protocol, and/or other like statistics.

Of course, any of the Ethernet LAN statistics may be used for any suitable type of network other than a LAN using any suitable protocol other than Ethernet.

### Exemplary SAN Statistics

As described above, a monitor may generate a variety of statistics, which, in some embodiments, may be used to trigger a bit sequence capture. In some embodiments, statistics may be generated for SANs.

In one embodiment, the SAN statistics may include a variety of Fibre Channel link metrics, which may include any combination of the following: the total number of frames of any type per second, the total megabytes of frame payload data per second (which may exclude the SOF, Header, CRC, and EOF portions of the frame), the total number of SCSI frames per second (which may include SCSI Command, Transfer Ready, Data and Status frames), the total megabytes of SCSI frame payload data per second (which may include SCSI Command, Transfer Ready, Data and Status frames, but may exclude the SOF, Header, CRC or EOF), the total number of Fibre Channel management fames per second (which may include Extended Link Services or ELS, Basic Link Services or BLS, Fibre Channel Services or FCS, Link Control or LC, and Fabric Frames or SOF(f)), the total megabytes of FC Management frame payload data per second (which may include ELS, BLS, FCS, LC, and SOF(f), but may exclude the SOF, Header, CRC or EOF), the total number of Non-Management and Non-SCSI frames per second, the total megabytes of Non-Management and Non-SCSI frame payload data per second (which may not include the SOF, Header, CRC or EOF), total application data frames per second (which may include solicited and unsolicited data frames), total megabytes of application payload data per second (which may include the payload of solicited and unsolicited data frames), the percentage of total theoretical bus capacity consumed by the payload bytes, the percentage of total theoretical bus capacity consumed by Fibre Channel management frames, the percentage of total theoretical bus capacity consumed by the SCSI frame payload bytes, the percentage of total theoretical bus capacity consumed by the Non-SCSI and Non-Management frame payload bytes, and/or other like statistics.

In one embodiment, the SAN statistics may include a variety of Fibre Channel link event statistics, which may include any combination of the following: the number of times a link has transitioned into a Loss of Sync state in an interval, the number of times a link has transitioned to a Loss of Signal state in an interval, the number of primitive sequences of LIP events (e.g., when a LIP event reinitializes the FC loop and thus cancels all outstanding I/O's), the number of primitive sequences of NOS and OLS events (e.g., when a NOS/OLS event reinitializes the FC link and thus cancels all outstanding I/O's), the number of Fibre Channel Extended Link Services Frames (such as, LOGO, PLOGI, ACC, and the like) in an interval, the number of Fibre Channel Services Frames (such as, Directory Server Management and FC-AL Management) in an interval, the number of Fabric Frames (such as, frames that begin with the SOF(f) primitive) in an interval, the number of Basic Link Services Frames (such as, ABTS, BA_ACC, BA_RJT, and the like) in an interval, the number of Link Control Frames (which may include P_RJT, F_RJT, F_BSY, and may exclude ACK) in an interval, the number of times a link has returned to an Idle state after any LOS, LOSIG, LIP or NOS/OLS events, the number of SCSI Check Condition Status Frames in an interval, the number of SCSI Bad Status Frames (which may include QueueFull, Busy, Condition Met, and the like; but may exclude SCSI Check Condition Status Frames) in an interval, the number of SCSI Task Management Frames (such as, Target Reset, LUN Reset, Clear ACA, and the like) in an interval, the number of FC Code Violations (such as, a bit error or a disparity error that occurred in a Fibre Channel word) in an interval, framing errors that may occur on any link with media or transmission problems (such as, bad or missing CRC; bad or missing SOF/EOF values; improperly truncated frames, such as, jabber or runt frames; EOFa, EOFni, and EOFdti frames; and the like), and/or other like statistics.

In one embodiment, the SAN statistics may include a variety of Fibre Channel link group statistics, which may include any combination of the following: the number of Login type frames (such as, FLOGI, PLOGI, PRLI, ADISC, PDISC, and FDISC frames) in an interval, the number of Logout type frames (such as, LOGO, PRLO, and TPRLO frames) in an interval, the number of ABTS frames in an interval, the number of Notification type frames (such as, FAN and RSCN frames) in an interval, the number of Reject type frames (such as, LS_RJT, BA_RJT, P_RJT, and F_RJT frames) in an interval, the number of Busy type frames (such as, P_BSY and F_BSY frames) in an interval, the number of Accept type frames (such as, BA_ACC and ACC frames) in an interval, the number of Loop Initialization frames (such as, LISM, LIFA, LIPA, LIHA, LISA, LIRP, and LILP frames) in an interval, and/or other like statistics.

In one embodiment, the SAN statistics may include a variety of SCSI link pending exchange statistics, which may include any combination of the following: the number of exchanges that have been opened, but not closed in an interval; the maximum number of exchanges open at one time during an interval, and/or other like statistics. In one embodiment, the SAN statistics may include a variety of initiator-target/LUN statistics, such as, for conversations between a given initiator and a given SCSI target and/or Logical Unit Number (collectively ITL). The initiator-target/LUN statistics may include any combination of the following: the amount of overall bus capacity utilized by SCSI exchanges between the specified ITL, the number of frames per second used by SCSI exchanges between the specified ITL, the frames/sec metric for the specified ITL expressed as a percentage of all frames sent this second, the number of megabytes of frame payload sent per second between the specified ITL (which may exclude the SOF, Header, CRC or EOF), the MB/sec metric for the specified ITL expressed as a percentage of all MB sent this second, the number of SCSI Task Management Frames (such as, Target Reset, LUN Reset, Clear ACA, and the like) for the specified ITL in an interval, the number of SCSI Bad Status Frames (which may include QueueFull, Busy, Condition Met, but may exclude SCSI Check Condition Status Frames) for the specified ITL in an interval, the number of SCSI Check Condition Status Frames for this ITL in an interval, the number of SCSI exchanges aborted during this interval, and/or other like statistics.

In one embodiment, the SAN statistics may include a variety of initiator-target/LUN statistics for a storage device, which may include any combination of the following: the total amount of elapsed time from the SCSI Read Command to the First Data for all exchanges for a specified ITL that completed in an interval, the average amount of elapsed time from the SCSI Read Command to the First Data for all exchanges for a specified ITL that completed in an interval, the minimum amount of elapsed time from the SCSI Read Command to the First Data for all exchanges for a specified ITL that completed in an interval, the maximum amount of elapsed time from the SCSI Read Command to the First Data for all exchanges for a specified ITL that completed in an interval, and/or other like statistics.

In one embodiment, the SAN statistics may include a variety of initiator-target/LUN statistics for various types of exchanges, such as, a read exchange, a write exchange, or other exchange. The ITL exchange statistics may include any combination of the following: the total number of frames per second used by the exchanges between the specified ITL, the total number of megabytes per second used by the exchanges between the specified ITL (which may include the SOF, Header, CRC or EOF), the number of commands issued for the specified ITL in an interval, the number of commands completed for the specified ITL in an interval, the total amount of elapsed time for the SCSI exchanges for the specified ITL that completed in an interval, the average amount of elapsed time per SCSI exchange for the specified ITL that completed in an interval, the minimum amount of elapsed time per SCSI exchange for the specified ITL that completed in this interval, the maximum amount of elapsed time per SCSI exchange for the specified ITL that completed in an interval, the minimum number of data bytes requested for any SCSI exchange for the specified ITL that completed in an interval, the maximum number of data bytes requested for any SCSI exchange for the specified ITL that completed in an interval, and/or other like statistics.

In one embodiment, the SAN statistics may include a variety of SCSI link pending exchange statistics for a specified, which may include any combination of the following: the number of exchanges that have been opened, but not closed in an interval; the maximum number of exchanges open at one time during an interval, and/or other like statistics.

In one embodiment, the SAN statistics may include a variety of SCSI status metrics that indicate one or more of the following: a SCSI status value associated with a frame, one or more sense codes associated with a frame, a timestamp indicating when the frame was observed, an ITL value, and any other suitable information.

In one embodiment, the SAN statistics may include any of a variety of vSAN statistics for at least one vSAN.

Of course, any of the SAN statistics may be used for any suitable type of network other than a SAN or vSAN using any suitable protocol other than Fibre Channel.

### Exemplary Operating and Computing Environments

The methods and systems described above can be implemented using software, hardware, or both hardware and software. For example, the software may advantageously be configured to reside on an addressable storage medium and be configured to execute on one or more processors. Thus, software, hardware, or both may include, by way of example, any suitable module, such as software components, object-oriented software components, class components and task components, processes, functions, attributes, procedures, subroutines, segments of program code, drivers, firmware, microcode, circuitry, data, databases, data structures, tables, arrays, variables, field programmable gate arrays (“FPGA”), a field programmable logic arrays (“FPLAs”), a programmable logic array (“PLAs”), any programmable logic device, application-specific integrated circuits (“ASICs”), controllers, computers, and firmware to implement those methods and systems described above. The functionality provided for in the software, hardware, or both may be combined into fewer components or further separated into additional components. Additionally, the components may advantageously be implemented to execute on one or more computing devices. As used herein, “computing device” is a broad term and is used in its ordinary meaning and includes, but is not limited to, devices such as, personal computers, desktop computers, laptop computers, palmtop computers, a general purpose computer, a special purpose computer, mobile telephones, personal digital assistants (PDAs), Internet terminals, multi-processor systems, hand-held computing devices, portable computing devices, microprocessor-based consumer electronics, programmable consumer electronics, network PCs, minicomputers, mainframe computers, computing devices that may generate data, computing devices that may have the need for storing data, and the like.

Also, one or more software modules, one or more hardware modules, or both may comprise a means for performing some or all of any of the methods described herein. Further, one or more software modules, one or more hardware modules, or both may comprise a means for implementing any other functionality or features described herein.

Embodiments within the scope of the present invention also include computer-readable media for carrying or having computer-executable instructions or data structures stored thereon. Such computer-readable media can be any available media that can be accessed by a computing device. By way of example, and not limitation, such computer-readable media can comprise any storage device or any other medium which can be used to carry or store desired program code means in the form of computer-executable instructions or data structures and which can be accessed by a computing device.

When information is transferred or provided over a network or another communications connection (either hardwired, wireless, or a combination of hardwired or wireless) to a computer, the computer properly views the connection as a computer-readable medium. Thus, any such connection is properly termed a computer-readable medium. Combinations of the above should also be included within the scope of computer-readable media. Computer-executable instructions comprise, for example, instructions and data which cause a computing device to perform a certain function or group of functions. Data structures include, for example, data frames, data packets, or other defined or formatted sets of data having fields that contain information that facilitates the performance of useful methods and operations. Computer-executable instructions and data structures can be stored or transmitted on computer-readable media, including the examples presented above.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A network diagnostic system comprising:
a network diagnostic module configured to perform one or more network diagnostic functions, the network diagnostic module comprising:
a first logic module, the first logic module being configured to receive a plurality of network messages from a network; to process the plurality of network messages into at least one message having an alternate structure; and to send the at least one message having an alternate structure to an analysis module; the analysis module being configured to receive messages that have the alternate structure and to perform at least one network diagnostic function using the received messages that have the alternate structure;
the alternate structure including inter-packet meta-data adapted to describe one or more network messages that occurred between a first network message of the plurality of network messages and a second network message of the plurality of network messages.

2. The network diagnostic system as in claim 1, wherein the network supports a first bandwidth, the first bandwidth being the sum of the bandwidths of the plurality of communication paths; wherein the analysis module supports up to a second bandwidth, the second bandwidth being less than the first bandwidth; and wherein the first logic module is configured to send the at least one message having an alternate structure to the analysis module via a bandwidth supported by the analysis module.

3. The network diagnostic system as in claim 1, wherein the network diagnostic module further comprises:
an analysis module, the analysis module being configured to receive the at least one message having an alternate structure and to perform at least one network diagnostic function using the at least one message having an alternate structure.

4. The network diagnostic system of claim 3, further comprising:
a second logic module configured to receive, from the analysis module, network diagnostic data generated using the at least one message having an alternate structure and to transmit the network diagnostic data to a processor for client retrieval.

5. The network diagnostic system as in claim 3, wherein the analysis module comprises a network processor unit.

6. The network diagnostic system of claim 1, wherein the network diagnostic module is configurable to perform any of a plurality of network diagnostic functions using the plurality of network messages from a network.

7. The network diagnostic system of claim 1, wherein the network diagnostic module is configurable to perform one or more network diagnostic functions using network messages from any of a plurality of network protocols.

8. The network diagnostic system of claim 1, wherein the network diagnostic module is configurable to perform one or more network diagnostic functions using network messages from any of a plurality of serial protocols.

9. The network diagnostic system of claim 1, wherein the network diagnostic module is configurable to perform one or more network diagnostic functions using network messages from any of a plurality of physical-layer protocols.

10. The network diagnostic system as in claim 1, wherein first logic module comprises a field programmable gate array.

11. The network diagnostic system of claim 1, further comprising a printed circuit board that includes the network diagnostic module.

12. The network diagnostic system of claim 1, further comprising a chassis computing system that includes at least one blade that includes the network diagnostic module.

13. The network diagnostic system of claim 1, further comprising an appliance that includes the network diagnostic module and a storage device.

14. The network diagnostic system of claim 1, wherein the one or more network diagnostic functions comprise any of the following network diagnostic functions:
a protocol-analyzer network diagnostic function comprising:
receiving a first bit sequence comprising at least one network message;
comparing at least a portion of the first bit sequence with a second bit sequence; and
in response to the comparison, executing a capture of a third bit sequence comprising at least a portion of a network message; and a monitor network diagnostic function comprising:
receiving a first bit sequence comprising at least one network message;
comparing at least a portion of the first bit sequence with a second bit sequence; and
in response to the comparison, generating one or more statistics.

15. A network diagnostic system comprising:
a network diagnostic module configured to perform one or more network diagnostic functions, the network diagnostic module comprising:
an analysis module, the analysis module being configured to receive one or more messages and to perform at least one network diagnostic function using the one or more messages, the analysis module being configured to support up to a first bandwidth; and
a first logic module, the first logic module being configured to receive a plurality of network messages from a network, the network supporting a second bandwidth that is greater than the first bandwidth; to process the plurality of network messages into at least one message having an alternate structure; and to send the at least one message having an alternate structure to an analysis module via a bandwidth supported by the analysis module;
the alternate structure including inter-packet meta-data adapted to describe one or more network messages that occurred between a first network message of the plurality of network messages and a second network message of the plurality of network messages.

16. The network diagnostic system of claim 15, wherein the network diagnostic module is configurable to perform any of a plurality of network diagnostic functions using the plurality of network messages from the network.

17. The network diagnostic system of claim 15, wherein the network diagnostic module is configurable to perform one or more network diagnostic functions using network messages from any of a plurality of network protocols.

18. The network diagnostic system of claim 15, wherein the network diagnostic module is configurable to perform one or more network diagnostic functions using network messages from any of a plurality of serial protocols.

19. The network diagnostic system of claim 15, wherein the network diagnostic module is configurable to perform one or more network diagnostic functions using network messages from any of a plurality of physical-layer protocols.

20. The network diagnostic system of claim 15, further comprising:
a second logic module configured to receive, from the analysis module, network diagnostic data generated using the at least one message having an alternate structure and to transmit the network diagnostic data to a processor for client retrieval.
